(19) United States
(12) Patent Application Publication
(10) Pub. No.: US 2024/0397753 A1
(43) Pub. Date: Nov. 28, 2024

(54) DISPLAY DEVICE

(71) Applicant: Samsung Display Co., LTD., Yongin-si (KR)

(72) Inventors: Joon Yong PARK, Yongin-si (KR); Hyun Eok SHIN, Yongin-si (KR); Su Kyoung YANG, Yongin-si (KR); Dong Min LEE, Yongin-si (KR)

(21) Appl. No.: 18/595,810

(22) Filed: Mar. 5, 2024

(30) Foreign Application Priority Data
May 26, 2023 (KR) 10-2023-0068694

(51) Int. Cl. H10K 59/122; H10K 59/80; H10K 102/00

(52) U.S. Cl. CPC H10K 59/122; H10K 59/873; H10K 2102/351

(57) ABSTRACT

A display device includes a first electrode on a substrate; a pixel-defining layer disposed on the substrate and defining a first opening overlapping the first electrode, a bank structure disposed on the pixel-defining layer and defining a second opening overlapping the first opening; a first emissive layer disposed on the first electrode and disposed in the first opening; and a second electrode disposed on the first emissive layer and contacting the bank structure in the second opening. The bank structure includes a first base disposed on the pixel-defining layer and including a conductive material, and a second base disposed on the first base and including a tip protruding toward the first opening. The second base includes a first bank layer disposed on the first base and including a transparent conductive material, and a second bank layer disposed on the first bank layer and including a conductive material.

This application claims priority to Korean Patent Application No. 10-2023-0068694, filed on May 26, 2023, and all the benefits accruing therefrom under 35 U.S.C. § 119, the content of which in its entirety is herein incorporated by reference.

### BACKGROUND

### 1. Field

The disclosure relates to a display device.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions. Display devices may be flat-panel display devices such as a liquid-crystal display device, a field emission display device, and an organic light-emitting display device. Among such flat panel display devices, a light-emitting display device includes a light-emitting element that may emit light on its own, so that each of the pixels of the display panel may emit light by themselves. Accordingly, a light-emitting display device may display images without a backlight unit that supplies light to the display panel.

### SUMMARY

Features of the disclosure provide a display device that may reduce reflectance of external light and may improve display quality.

It should be noted that features of the disclosure are not limited to the above-mentioned feature; and other features of the disclosure will be apparent to those skilled in the art from the following descriptions.

By embodiments of the disclosure, a bank structure includes a double film having low-reflection characteristics in a display device, so that the reflectance of external light in the display device may be reduced.

By embodiments of the disclosure, a bank structure includes a double film having low-reflection characteristics in a display device, so that the display quality may be improved.

An embodiment of a display device includes a display device including a substrate; a first electrode disposed on the substrate; a pixel-defining layer disposed on the substrate and defining a first opening overlapping with the first electrode, a bank structure disposed on the pixel-defining layer and defining a second opening overlapping with the first opening; a first emissive layer disposed on the first electrode and disposed in the first opening; and a second electrode disposed on the first emissive layer and in contact with the bank structure in the second opening, where the bank structure includes a first base disposed on the pixel-defining layer and including a conductive material, and a second base disposed on the first base and including a tip protruding toward the first opening than a side surface of the first base, and where the second base includes a first bank layer disposed on the first base and including a transparent conductive material, and a second bank layer disposed on the first bank layer and including a conductive material different from that of the first bank layer.

In an embodiment, a thickness of the first bank layer in a direction perpendicular to the substrate may be greater than a thickness of the second bank layer.

In an embodiment, a refractive index of the first bank layer may be smaller than a refractive index of the second bank layer.

In an embodiment, an amount of lights reflected by the bank structure may be reduced by destructive interference between first light incident through the second base and reflected light reflected from a surface of the first base toward the outside.

In an embodiment, the first bank layer may include indium-zinc oxide (“IZO”), and the second bank layer may include titanium (Ti).

In an embodiment, the display may include the thickness of the first bank layer ranges from 400 angstroms (Å) to 500 Å, and the thickness of the second bank layer ranges from 100 Å to 150 Å.

In an embodiment, one surface of the first emissive layer and one surface of the second electrode may contact the first base in the second opening, where a contact area of the first emissive layer in contact with the first base may be smaller than a contact area of the second electrode in contact with the first base.

In an embodiment, the first base may further include a first base bank layer disposed on the pixel-defining layer and including a same material as that of the second bank layer; and a second base bank layer disposed on the first base bank layer and including a conductive material different from that of the first base bank layer.

In an embodiment, the first base bank layer may further include a first surface in contact with the pixel-defining layer, a second surface facing the first surface, and a side surface, where the first surface of the first base bank layer covers an entirety of a surface of the pixel-defining layer, where the side surface of the first base bank layer protrudes toward the first opening than a side surface of the second base bank layer, and where the second surface and the side surface of the first base bank layer are partially in contact with the first emissive layer.

In an embodiment, the first base bank layer may include titanium (Ti), and the second base bank layer may include copper (Cu).

In an embodiment, the display device may further include a thickness of the second base bank layer in a direction perpendicular to the substrate is greater than a thickness of the first base bank layer in the direction perpendicular to the substrate, where the thickness of the first base bank layer ranges from 100 Å to 150 Å, and where the thickness of the second base bank layer ranges from 5,000 Å to 8,000 Å.

In an embodiment, the display device may further include a third electrode spaced apart from the first electrode with the pixel-defining layer therebetween. a second emissive layer on the third electrode; a fourth electrode on the second emissive layer; and a thin-film encapsulation layer disposed on the second electrode, the bank structure, and the fourth electrode, where the thin-film encapsulation layer includes a first encapsulation layer; a second encapsulation layer on the first encapsulation layer; and a third encapsulation layer on the second encapsulation layer, where the first encapsulation layer may further include a first inorganic layer disposed on the second electrode and the second bank layer; and a second inorganic layer disposed on the fourth electrode and the second bank layer, and where the first inorganic layer and the second inorganic layer may be spaced apart from each other.

In an embodiment, the second bank layer and the second encapsulation layer may contact each other where the first inorganic layer and the second inorganic layer included in the first encapsulation layer are spaced apart from each other.

In an embodiment, the display device may further include a first organic pattern disposed on the second bank layer of the second base to surround the first opening, and including a same material as that of the first emissive layer; and a first electrode pattern disposed on the first organic pattern and including a same material as that of the second electrode, where the first organic pattern and the first electrode pattern overlap with the tip of the second base, where the first emissive layer and the first organic pattern are spaced apart from each other, and where the second electrode and the first electrode pattern are spaced apart from each other.

In an embodiment, the display device may further include a pattern disposed between the first electrode and the pixel-defining layer, where the pattern overlaps with the tip of the second base and the second opening, and where the pattern is surrounded by the first emissive layer, the pixel-defining layer and the first electrode.

In an embodiment, the pattern may include aluminum-zinc oxide (“AZO”) doped with aluminum, and a content of aluminum (Al) in the pattern ranges from 2% to 5%.

An embodiment of a display device includes a substrate; a first electrode disposed on the substrate; a pixel-defining layer disposed on the substrate and defining a first opening overlapping with the first electrode; a bank structure disposed on the pixel-defining layer and defining a second opening overlapping with the first opening; a first emissive layer disposed on the first electrode and disposed in the first opening; and a second electrode disposed on the first emissive layer and in contact with the bank structure in the second opening, where the bank structure includes a first base disposed on the pixel-defining layer and including a conductive material, and a second base disposed on the first base and including a tip protruding toward the first opening than a side surface of the first base, and where a cavity is defined between a surface of the first electrode and the pixel-defining layer, where the first emissive layer is further disposed in the cavity, and where the cavity overlaps with the second opening and the tip of the second base.

In an embodiment, the cavity may be surrounded by the first emissive layer, the pixel-defining layer and the first electrode, where a pattern and a space are further disposed in the cavity, and where the space is disposed between the pattern and the first emissive layer.

In an embodiment, the pattern may include aluminum-zinc oxide (“AZO”), and a content of aluminum (Al) in the pattern ranges from 2% to 5%.

In an embodiment, the display device may further include a space disposed in the cavity, where the space is surrounded by the first emissive layer, the pixel-defining layer and the first electrode, and overlaps with the tip of the bank structure and the second opening.

It should be noted that effects of the disclosure are not limited to those described above and other effects of the disclosure will be apparent to those skilled in the art from the following descriptions.

### BRIEF DESCRIPTION OF THE DRAWINGS

These and/or other features of embodiments of the invention will become apparent and more readily appreciated from the following description of the embodiments, taken in conjunction with the accompanying drawings, in which:

FIG. 1 is a perspective view of an embodiment of an electron device according to the disclosure.

FIG. 2 is a perspective view showing an embodiment of a display device included in an electron device according to the disclosure.

FIG. 3 is a cross-sectional view of the display device of FIG. 2 seen from the side.

FIG. 4 is a plan view showing an embodiment of a display layer of a display device according to the disclosure.

FIG. 5 is a plan view showing arrangement of emission areas in a first display area of a display device.

FIG. 6 is a cross-sectional view taken along line X1-X1′ of FIG. 5.

FIG. 7 is an enlarged cross-sectional view of the first emission area of FIG. 6.

FIG. 8 is an enlarged cross-sectional view of area A of FIG. 7.

FIG. 9 is an enlarged, cross-sectional view of area C of FIG. 6.

FIG. 10 is an enlarged, cross-sectional view of the first emission area of FIG. 6.

FIG. 11 is an enlarged cross-sectional view of area E of FIG. 10.

FIG. 12 is an enlarged, cross-sectional view of area E of FIG. 10.

### DETAILED DESCRIPTION

Embodiments of the disclosure will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached drawing figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The term “lower,” may therefore, encompasses both an orientation of “lower” and “upper,” depending on the particular orientation of the figure. Similarly, when the device in one of the drawing figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments of the disclosure will be described with reference to the accompanying drawings.

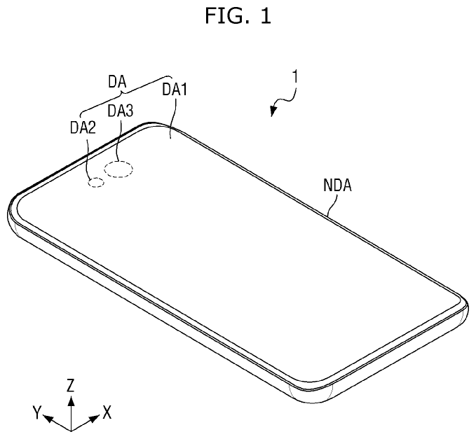

FIG. 1 is a plan view of an embodiment of a display device according to the disclosure.

Referring to FIG. 1, an electronic device 1 displays a moving image or a still image. The electronic device 1 may refer to any electronic device that provides a display screen. In an embodiment, the electronic device 1 may include a television set, a laptop computer, a monitor, an electronic billboard, the Internet of Things devices, a mobile phone, a smart phone, a tablet personal computer (“PC”), an electronic watch, a smart watch, a watch phone, a head-mounted display device, a mobile communications terminal, an electronic notebook, an electronic book, a portable multimedia player (“PMP”), a navigation device, a game console and a digital camera, a camcorder, etc., for example.

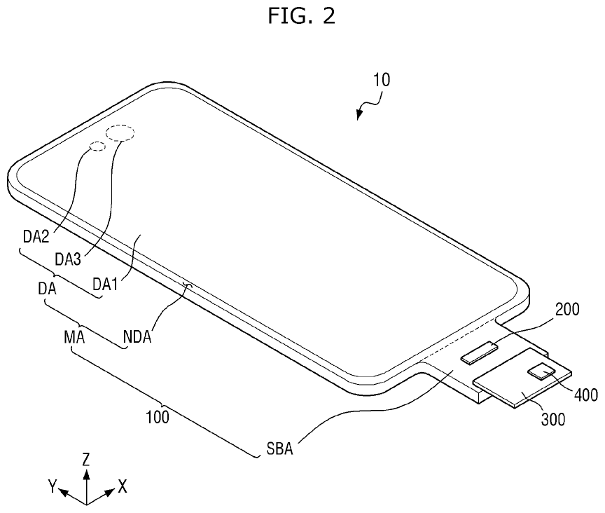

The electronic device 1 may include a display device 10 (refer to FIG. 2) for providing a display screen. In embodiments, the display device may include an inorganic light-emitting diode display device, an organic light-emitting display device, a quantum-dot light-emitting display device, a plasma display device, a field emission display device, etc. In the following description, an organic light-emitting diode display device is employed in an embodiment of the display device 10, but the disclosure is not limited thereto. Any other display device may be employed as long as the technical idea of the disclosure may be equally applied.

The shape of the electronic device 1 may be modified in a variety of ways. In an embodiment, the electronic device 1 may have shapes such as a rectangle with longer lateral sides, a rectangle with longer vertical sides, a square, a quadrangle with rounded corners (vertices), other polygons, a circle, etc., for example. The shape of a display area DA of the electronic device 1 may also be similar to the overall shape of the electronic device 1. In the example shown in FIG. 1, the electronic device 1 has a quadrangular, e.g., rectangular shape with the longer sides in the second direction Y.

The electronic device 1 may include the display area DA and a non-display area NDA. In the display area DA, images may be displayed. In the non-display area NDA, images are not displayed. The display area DA may be also referred to as an active area, while the non-display area NDA may also be also referred to as an inactive area. The display area DA may generally occupy the center of the electronic device 1.

The display area DA may include a first display area DA1, a second display area DA2 and a third display area DA3. In the second display area DA2 and the third display area DA3, components for adding a variety of features to the electronic device 1 may be disposed.

FIG. 2 is a perspective view showing an embodiment of a display device included in an electron device according to the disclosure.

Referring to FIG. 2, the electronic device 1 in the embodiment of the disclosure may include a display device 10. The display device 10 may provide a display screen where images are displayed in the electronic device 1. The display device 10 may have a shape similar to that of the electronic device 1 when viewed from the top. In an embodiment, the display device 10 may have a shape similar to a rectangle having shorter sides in the first direction X and longer sides in the second direction Y when viewed from the top, for example. The corners where the shorter sides in the first direction X meet the longer sides in the second direction Y may be rounded with a predetermined curvature. It should be understood, however, that the disclosure is not limited thereto. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA.

The main area MA may include the display area DA including pixels for displaying images, and the non-display area NDA disposed around the display area DA.

The display area DA may include the first display area DA1, the second display area DA2 and the third display area DA3. The display area DA may output lights from a plurality of emission areas or a plurality of open areas.

The non-display area NDA may be disposed on the outer side of the display area DA.

The non-display area NDA may be defined as the edge area of the main area MA of the display panel 100.

The subsidiary area SBA may be extended from one side of the main area MA. The subsidiary area SBA may include a flexible material that may be bent, folded, or rolled. In an embodiment, when the subsidiary area SBA is bent, the subsidiary area SBA may overlap the main area MA in the thickness direction (third direction Z), for example. The subsidiary area SBA may include pads connected to the display driver 200 and the circuit board 300. In another embodiment, the subsidiary area SBA may be eliminated, and the display driver 200 and the pads may be disposed in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (“IC”) and may be attached on the display panel 100 by a chip-on-glass (“COG”) technique, a chip-on-plastic (“COP”) technique, or ultrasonic bonding. In an embodiment, the display driver 200 may be disposed in the subsidiary area SBA and may overlap with the main area MA in the thickness direction as the subsidiary area SBA is bent, for example. In another embodiment, the display driver 200 may be disposed (e.g., mounted) on the circuit board 300.

The circuit board 300 may be attached on the pad area of the display panel 100 using an anisotropic conductive film (“ACF”). Lead lines of the circuit board 300 may be electrically connected to the pads of the display panel 100. The circuit board 300 may be a flexible printed circuit board (“FPCB”), a printed circuit board (“PCB”), or a flexible film such as a chip-on-film (“COF”).

The touch driver 400 may be disposed (e.g., mounted) on the circuit board 300. The touch driver 400 may be connected to a touch sensing unit of the display panel 100. The touch driver 400 may supply a touch driving signal to a plurality of touch electrodes of the touch sensing unit and may sense a change in the capacitance between the plurality of touch electrodes. In an embodiment, the touch driving signal may be a pulse signal having a predetermined frequency, for example. The touch driver 400 may determine whether there is an input and may find the coordinates of the input based on the amount of the change in the capacitance between the touch electrodes. The touch driver 400 may be implemented as an integrated circuit (“IC”).

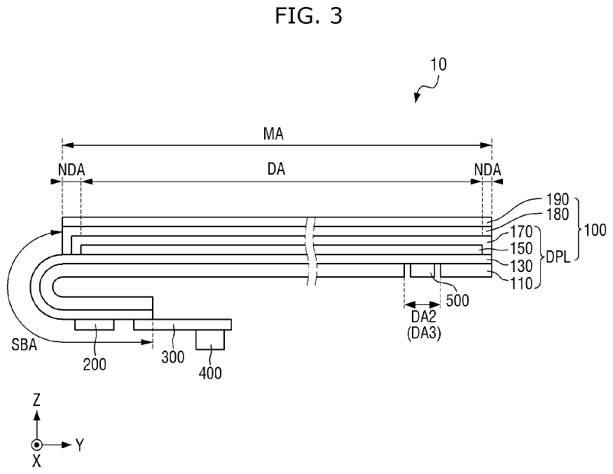

FIG. 3 is a cross-sectional view of the display device 10 of FIG. 2 seen from the side.

Referring to FIG. 3, the display panel 100 may include a display layer DPL, a touch sensing layer 180, and a color filter layer 190. The display layer DPL may include a substrate 110, a thin-film transistor layer 130, an emission material layer 150, a thin-film encapsulation layer 170.

The substrate 110 may be a base substrate or a base member. The substrate 110 may be a flexible substrate that may be bent, folded, or rolled. In an embodiment, the substrate 110 may include a polymer resin such as polyimide (“PI”), a glass material, and a metal material, for example.

The thin-film transistor layer 130 may be disposed on the substrate 110. The thin-film transistor layer 130 may overlap the display area DA, the non-display area NDA, and the subsidiary area SBA. The thin-film transistor layer 130 may include a plurality of thin-film transistors and a plurality of signal lines. A plurality of thin-film transistors may be disposed in the display area DA, and a plurality of signal lines may be disposed in the non-display area NDA.

The emission material layer 150 may be disposed on the thin-film transistor layer 130. The emission material layer 150 may include a pixel circuit, a pixel-defining layer, and a self-light-emitting element. In an embodiment, the self-light-emitting element may include, but is not limited to, at least one of: an organic light-emitting diode including an organic emissive layer, a quantum-dot light-emitting diode (“quantum LED”) including a quantum-dot emissive layer, an inorganic light-emitting diode (“inorganic LED”) including an inorganic semiconductor, and a micro light-emitting diode (“micro LED”), for example.

The thin-film encapsulation layer 170 may cover the upper and side surfaces of the emission material layer 150, and may protect the emission material layer 150. The thin-film encapsulation layer 170 may include at least one inorganic film and at least one organic film for encapsulating the emission material layer 150.

The touch sensing layer 180 may be disposed on the thin-film encapsulation layer 170. The touch sensing layer 180 may include a plurality of touch electrodes and a plurality of touch lines. Specifically, the touch electrodes may sense a user's touch by capacitive sensing. In addition, the touch lines may connect the touch electrodes with the touch driver 400. The touch electrodes may overlap with the display area DA. The touch lines may be disposed in a touch peripheral area overlapping with the non-display area NDA. In an embodiment, the touch sensing layer 180 may sense a user's touch by mutual capacitance sensing or self-capacitance sensing, for example.

In some embodiments, the display device 10 may further include an optical device 500. The optical device 500 may be disposed in the second display area DA2 or the third display area DA3. The optical device 500 may output or receive light in infrared, ultraviolet, and visible ranges. In an embodiment, the optical device 500 may be an optical sensor that senses light incident on the display device 10, such as a proximity sensor, an illuminance sensor, a camera sensor and an image sensor, for example.

The color filter layer 190 may be disposed on the thin-film encapsulation layer 170. The color filter layer 190 may include a plurality of color filters associated with the plurality of emission areas, respectively. Each of the color filters may selectively transmit light of a particular wavelength and block or absorb lights of other wavelengths. The color filter layer 190 may absorb some of lights introduced from the outside of the display device 10 to reduce the reflection of external light. Accordingly, the color filter layer 190 may prevent distortion of colors due to the reflection of external light.

The color filter layer 190 may be disposed directly on the thin-film encapsulation layer 170. Accordingly, the display device 10 may not desire any separate substrate for the color filter layer 190.

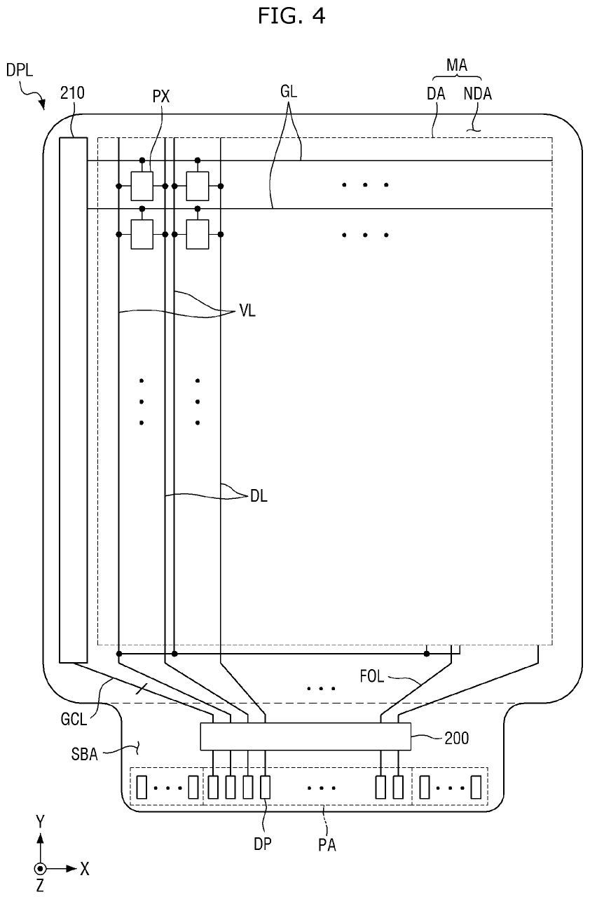

FIG. 4 is a plan view showing an embodiment of the display layer DPL of the display device 10.

Referring to FIG. 4, the display layer DPL may include the main area MA and the subsidiary area SBA. The main area MA may include the display area DA and the non-display area NDA.

The display area DA may be disposed at the center of display device 100. In the display area DA, pixels PX, gate lines GL, data lines DL and voltage lines VL may be disposed. Each of the pixels PX may be defined as the minimum unit that outputs light.

The plurality of gate lines GL may supply the gate signals received from the gate driver 210 to the plurality of pixels PX. The plurality of gate lines GL may be extended in the first direction X and may be spaced apart from one another in the second direction Y intersecting the first direction X.

The plurality of data lines DL may supply the data voltages received from the display driver 200 to the plurality of pixels PX. The data lines DL may be extended in the second direction Y and may be spaced apart from one another in the first direction X.

The plurality of voltage lines VL may supply the supply voltage received from the display driver 200 to the plurality of pixels PX. The supply voltage may be at least one of a driving voltage, an initialization voltage, a reference voltage and a low-level voltage. The plurality of voltage lines VL may be extended in the second direction Y and may be spaced apart from one another in the first direction X.

The non-display area NDA may surround the display area DA. In the non-display area NDA, the gate driver 210, fan-out lines FOL, and gate control lines GCL may be disposed. The gate driver 210 may generate a plurality of gate signals based on the gate control signal, and may sequentially supply the plurality of gate signals to the plurality of gate lines GL in a predetermined order.

The fan-out lines FOL may be extended from the display driver 200 to the display area DA. The fan-out lines FOL may supply the data voltage received from the display driver 200 to the plurality of data lines DL.

A gate control line GCL may be extended from the display driver 200 to the gate driver 210. The gate control line GCL may supply the gate control signal received from the display driver 200 to the gate driver 210.

The subsidiary area SBA may include the display driver 200 and a pad area PA.

The display driver 200 may output signals and voltages for driving the display panel 100 to the fan-out lines FOL. The display driver 200 may supply data voltages to the data lines DL through the fan-out lines FOL. The data voltages may be applied to the plurality of pixels PX, so that the luminance of the plurality of pixels PX may be controlled. The display driver 200 may supply a gate control signal to the gate driver 210 through the gate control lines GCL.

The pad area PA may be disposed at an edge of the subsidiary area SBA. The pad area PA may be electrically connected to the circuit board 300 using an anisotropic conductive film or a self assembly anisotropic conductive paste (“SAP”).

The pad area PA may include a plurality of display pads DP. The display pads DP may be connected to a graphic system through the circuit board 300. The plurality of display pads DP may be connected to the circuit board 300 to receive digital video data and may supply the digital video data to the display driver 200.

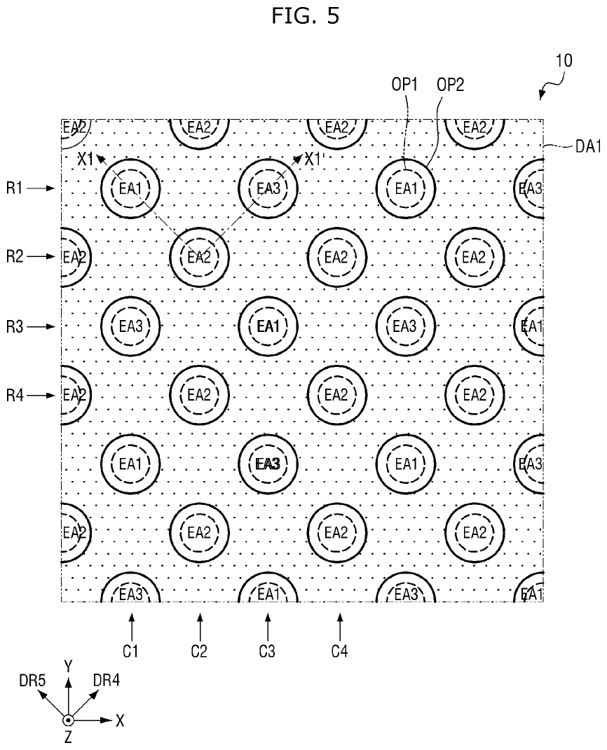

FIG. 5 is a plan view showing an embodiment of arrangement of emission areas in a first display area of a display device.

Referring to FIG. 5, the display device 10 may include a plurality of emission areas EA1, EA2 and EA3 arranged in the display area DA. The display area DA shown in FIG. 5 is the first display area DA1, and a plurality of emission areas EA1, EA2 and EA3 may be disposed in the first display area DAL. It should be understood, however, that a plurality of emission areas EA1, EA2 and EA3 may be disposed in the second display area DA2 and the third display area DA3 of the display area DA.

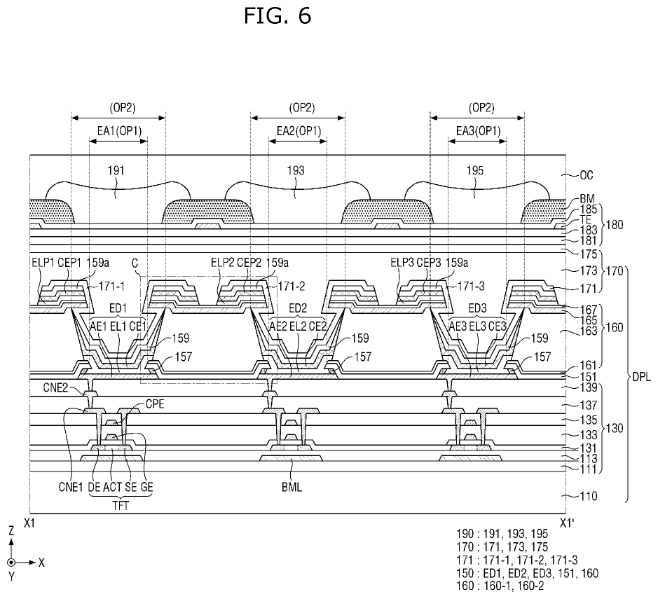

The emission areas EA1, EA2 and EA3 may include first emission areas EA1, second emission areas EA2 and third emission areas EA3 that emit lights of different colors. The first to third emission areas EA1, EA2 and EA3 may emit red, green and blue lights, respectively. The colors of lights emitted from the emission areas EA1, EA2 and EA3 may vary depending on the type of light-emitting elements ED1, ED2 and ED3 (refer to FIG. 6). In an embodiment of the disclosure, the first emission area EA1 emits first light of red color, the second emission area EA2 emits second light of green color, and the third emission area EA3 emits third light of blue color. It is, however, to be understood that the disclosure is not limited thereto.

The emission areas EA1, EA2 and EA3 may be arranged in a PenTile™ matrix, e.g., a diamond PenTile™ matrix. In an embodiment, the first emission area EA1 and the third emission area EA3 are spaced apart from each other in the first direction X, and may be arranged alternately in the first direction X and the second direction Y, for example. With regard to the emission areas EA1, EA2 and EA3, the first emission area EA1 and the third emission area EA3 may be arranged alternately in the first direction X in the first row R1 and the third row R3. In the first column C1 and the third column C3, the first emission area EA1 and the third emission area EA3 may be arranged alternately in the second direction Y.

A second emission area EA2 may be spaced apart from another adjacent second emission area EA2 in the first direction X and the second direction Y, and may be spaced apart from an adjacent first emission area EA1 and a third emission area EA3 in a fourth direction DR4 or a fifth direction DR5. A plurality of second emission areas EA2 may be repeatedly arranged in the first direction X and the second direction Y, and the second emission area EA2 and the first emission area EA1, or the second emission area EA2 and the third emission area EA3 may be arranged alternately in the fourth direction DR4 or the fifth direction DR5. With regard to the arrangement of the emission areas EA1, EA2 and EA3, second emission areas EA2 may be arranged repeatedly in the first direction X in the second row R2 and the fourth row R4, and second emission areas EA2 may arranged be repeatedly in the second direction Y in the second column C2 and the fourth column C4.

FIG. 6 is a cross-sectional view of the display device 10 of FIG. 5, taken along line X1-X1′.

Referring to FIG. 6, the display device 10 may include the display layer DPL, the touch sensing layer 180, the color filter layer 190 and an overcoat layer OC. The display layer DPL may include the substrate 110, the thin-film transistor layer 130, the emission material layer 150, the thin-film encapsulation layer 170.

The substrate 110 has been described above and thus will not be described again.

The thin-film transistor layer 130 may be disposed on the substrate 110. The thin-film transistor layer 130 may include a first buffer layer 111, a bottom metal layer BML, a second buffer layer 113, a thin-film transistor TFT, a gate insulator 131, a first inter-dielectric layer 133, a capacitor electrode CPE, a second inter-dielectric layer 135, a first connection electrode CNE1, a first passivation layer 137, a second connection electrode CNE2 and a second passivation layer 139.

The first buffer layer 111 may be disposed on the substrate 110. The first buffer layer 111 may include an inorganic film capable of preventing permeation of air or moisture. In an embodiment, the first buffer layer 111 may include a plurality of inorganic films stacked on one another alternately, for example.

The bottom metal layer BML may be disposed on the first buffer layer 111. In an embodiment, the bottom metal layer BML may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof, for example.

The second buffer layer 113 may cover the first buffer layer 111 and the bottom metal layer BML. The second buffer layer 113 may include an inorganic film capable of preventing permeation of air or moisture. In an embodiment, the second buffer layer 113 may include a plurality of inorganic films stacked on one another alternately, for example.

The thin-film transistor TFT may be disposed on the second buffer layer 113 and may form a pixel circuit of each of a plurality of pixels. In an embodiment, the thin-film transistor TFT may be a driving transistor or a switching transistor of the pixel circuit. The thin-film transistor TFT may include a semiconductor layer ACT, a source electrode SE, a drain electrode DE and a gate electrode GE, for example.

The semiconductor layer ACT may be disposed on the second buffer layer 113.

The semiconductor layer ACT may overlap the bottom metal layer BML and the gate electrode GE in the thickness direction and may be insulated from the gate electrode GE by the gate insulator 131. The material of a part of the semiconductor layer ACT may be made conductive to form the source electrode SE and the drain electrode DE.

The gate electrode GE may be disposed on the gate insulator 131. The gate electrode GE may overlap the semiconductor layer ACT with the gate insulator 131 interposed therebetween.

The gate insulator 131 may be disposed on the semiconductor layer ACT. In an embodiment, the gate insulator 131 may cover the semiconductor layer ACT and the second buffer layer 113, and may insulate the semiconductor layer ACT from the gate electrode GE, for example. The gate insulator 131 may include a contact hole through which the first connection electrode CNE1 passes.

The first inter-dielectric layer 133 may cover the gate electrode GE and the gate insulator 131. The first inter-dielectric layer 133 may include a contact hole through which the first connection electrode CNE1 passes. The contact hole of the first inter-dielectric layer 133 may be connected to the contact hole of the gate insulator (also referred to as a gate insulating layer) 131 and a contact hole of the second inter-dielectric layer 135.

The capacitor electrode CPE may be disposed on the first inter-dielectric layer 133.

The capacitor electrode CPE may overlap with the gate electrode GE in the thickness direction. The capacitor electrode CPE and the gate electrode GE may form a capacitance.

The second inter-dielectric layer 135 may cover the capacitor electrode CPE and the first inter-dielectric layer 133. The second inter-dielectric layer 135 may include a contact hole through which the first connection electrode CNE1 passes. The contact hole of the second inter-dielectric layer 135 may be connected to the contact hole of the first inter-dielectric layer 133 and the contact hole of the gate insulating layer 131.

The first connection electrode CNE1 may be disposed on the second inter-dielectric layer 135. The first connection electrode CNE1 may electrically connect the drain electrode DE of the thin-film transistor TFT with the second connection electrode CNE2. The first connection electrode CNE1 may be inserted into a contact hole defined in the second inter-dielectric layer 135, the first inter-dielectric layer 133 and the gate insulator 131 to contact the drain electrode DE of the thin-film transistor TFT.

The first passivation layer 137 may cover the first connection electrode CNE1 and the second inter-dielectric layer 135. The first passivation layer 137 may protect the thin-film transistor TFT. The first passivation layer 137 may include a contact hole through which the second connection electrode CNE2 passes.

The second connection electrode CNE2 may be disposed on the first protective layer 137. The second connection electrode CNE2 may electrically connect the first connection electrode CNE1 with the pixel electrodes AE1, AE2 and AE3 of the light-emitting elements ED1, ED2 and ED3. The second connection electrode CNE2 may be inserted into a contact hole defined in the first passivation layer 137 to contact the first connection electrode CNE1.

The second passivation layer 139 may cover the second connection electrode CNE2 and the first passivation layer 137. The second passivation layer 139 may include contact holes through which the pixel electrodes AE1, AE2 and AE3 of the light-emitting elements ED1, ED2 and ED3 pass.

The emission material layer 150 may be disposed on the thin-film transistor layer 130. The emission material layer 150 may include light-emitting elements ED1, ED2 and ED3, an inorganic pixel-defining layer 151, and a bank structure 160.

The display device 10 may include a plurality of light-emitting elements ED1, ED2 and ED3 disposed in different emission areas EA1, EA2 and EA3. The light-emitting elements ED1, ED2 and ED3 may include a first light-emitting element ED1 disposed in the first emission area EA1, a second light-emitting element ED2 disposed in the second emission area EA2, and a third light-emitting element ED3 disposed in the third emission area EA3. The light-emitting elements ED1, ED2 and ED3 may include pixel electrodes AE1, AE2 and AE3, emissive layers EL1, EL2 and EL3, and common electrodes CE1, CE2 and CE3, respectively. The light-emitting elements ED1, ED2 and ED3 disposed in different emission areas EA1, EA2 and EA3 may emit lights of different colors depending on the materials of the emissive layers EL1, EL2 and EL3. In an embodiment, the first light-emitting element ED1 disposed in the first emission area EA1 may emit red light of the first color, the second light-emitting element ED2 disposed in the second emission area EA2 may emit green light of the second color, and the third light-emitting element ED3 disposed in the third emission area EA3 may emit blue light of the third color, for example. The first to third emission areas EA1, EA2 and EA3 forming a single pixel may include the light-emitting elements ED1, ED2 and ED3 emitting lights of different colors to represent black-and-white or grayscale images. The light-emitting elements ED1, ED2 and ED3 may include the pixel electrodes AE1, AE2 and AE3, the emissive layers EL1, EL2 and EL3, and the common electrodes CE1, CE2 and CE3, respectively.

The pixel electrodes AE1, AE2 and AE3 may be disposed on the second passivation layer 139. The pixel electrodes AE1, AE2 and AE3 may be electrically connected to the drain electrode DE of the thin-film transistor TFT through the first and second connection electrodes CNE1 and CNE2.

The pixel electrodes AE1, AE2 and AE3 may be disposed in the emission areas EA1, EA2 and EA3, respectively. The pixel electrodes AE1, AE2 and AE3 may include a first pixel electrode AE1 disposed in the first emission area EA1, the second pixel electrode AE2 disposed in the second emission area EA2, and the third pixel electrode AE3 disposed in the third emission area EA3. The first pixel electrode AE l, the second pixel electrode AE2 and the third pixel electrode AE3 may be spaced apart from one another on the second passivation layer 139. The pixel electrodes AE1, AE2 and AE3 may be disposed in different emission areas EA1, EA2 and EA3 to form light-emitting elements ED1, ED2 and ED3 emitting lights of different colors.

In an embodiment of the disclosure, the pixel electrodes AE1, AE2 and AE3 may have a stack structure of a material layer having a relatively high work function such as indium-tin-oxide (“ITO”), indium-zinc-oxide (“IZO”), zinc oxide (ZnO) and indium oxide (In₂O₃), and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca) or any combinations thereof. A layer having a higher work function may be disposed on a higher layer than a reflective material layer so that it may be closer to the emissive layers EL1, EL2 and EL3. In an embodiment, the pixel electrodes AE1, AE2 and AE3 may have, but is not limited to, a multilayer structure of ITO/Mg, ITO/MgF, ITO/Ag, and ITO/Ag/ITO, for example.

The inorganic pixel-defining layer 151 may be disposed on the second passivation layer 139 and the pixel electrodes AE1, AE2 and AE3. The inorganic pixel-defining layer 151 may define first openings OP1 overlapping the emission areas EA1, EA2 and EA3. The inorganic pixel-defining layer 151 may overlap the first openings OP1 to expose parts of the pixel electrodes AE1, AE2 and AE3. The inorganic pixel-defining layer 151 may be disposed on the pixel electrodes AE1, AE2 and AE3 and may be spaced apart from the pixel electrodes AE1, AE2 and AE3.

The inorganic pixel-defining layer 151 may include an inorganic insulating material.

In an embodiment, the inorganic pixel-defining layer 151 may include aluminum oxide, titanium oxide, tantalum oxide, hafnium oxide, zinc oxide, silicon oxide, silicon nitride, and silicon oxynitride, for example.

Although not shown in the drawings, a temporary protective layer may be disposed between the inorganic pixel-defining layer 151 and the pixel electrodes AE1, AE2 and AE3 in the process of fabricating the display device 10. The temporary protective layer may be partially removed via a subsequent process. In other words, the temporary protective layer may be disposed between the inorganic pixel-defining layer 151 and the pixel electrodes AE1, AE2 and AE3, and the temporary protective layer may be partially removed during a subsequent etching process to form space in which the emissive layers EL1, EL2 and EL3 are disposed. Accordingly, the pixel electrodes AE1, AE2 and AE3 and the inorganic pixel-defining layer 151 may be spaced apart from each other in the third direction (z-axis direction). In some embodiments, a portion of the temporary protective layer that has not been removed may remain on the display device 10 as a residual pattern 157.

In some embodiments, the material of the temporary protective layer may desire a relatively high etch rate. This may be to reduce an etch loss of the bank structure 160 during the process of removing the temporary protective layer. The temporary protective layer may include an oxide semiconductor. In an embodiment, the temporary protective layer may be aluminum-zinc oxide (“AZO”) partially doped with aluminum (Al). In addition, the content of doped aluminum (Al) may range from 2% to 5%, for example. It should be understood, however, that the disclosure is not limited thereto. The temporary protective layer include indium gallium zinc oxide (“IGZO”), zinc tin oxide (“ZTO”), indium tin oxide (“IZO”), aluminum-zinc oxide (“AZO”; Aluminum doped Zinc Oxide), etc.

In some embodiments, the etch rate of aluminum-zinc oxide (“AZO”) doped with 2% to 5% of aluminum (Al) may be 18 times to 30 times the etch rate of the bank structure 160.

The bank structure 160 may be disposed on the inorganic pixel-defining layer 151. The bank structure 160 may define second openings OP2 overlapping with the emission areas EA1, EA2 and EA3. The second openings OP2 may be in line with the first openings OP1. The width of the second openings OP2 may be greater than that of the first openings OP1.

The bank structure 160 may include a conductive material. Accordingly, the bank structure 160 may electrically connect the common electrodes CE1, CE2 and CE3 disposed in the emission areas EA1, EA2 and EA3, respectively. As the area of the common electrodes CE1, CE2 and CE3 in contact with the bank structure 160 increases, the electrical resistance of the display device 10 may decrease.

The emissive layers EL1, EL2 and EL3 may be disposed on the pixel electrodes AE1, AE2 and AE3, respectively. When the thin-film transistors TFT apply predetermined voltages to the pixel electrodes AE1, AE2 and AE3, and the common electrodes CE1, CE2 and CE3 receive the common voltage or the cathode voltage, holes and electrons included in the emissive layers EL1, EL2 and EL3 may move to the emissive layers EL1, EL2 and EL3 through a hole transport layer and an electron transport layer, respectively. When holes and electrons combine with each other in the emissive layers EL1, EL2 and EL3, lights may exit.

The emissive layers EL1, EL2 and EL3 may include a first emissive layer EL1, a second emissive layer EL2, and a third emissive layer EL3 disposed in different emission areas EA1, EA2 and EA3. The first emissive layer EL1 may be disposed on the first pixel electrode AE1 in the first emission area EA1, the second emissive layer EL2 may be disposed on the second pixel electrode AE2 in the second emission area EA2, and the third emissive layer EL3 may be disposed on the third pixel electrode AE3 in the third emission area EA3. The first to third emissive layers EL1, EL2 and EL3 may be the emissive layers of the first to third light-emitting elements ED1, ED2 and ED3, respectively. The first emissive layer EL1 may emit red light of the first color, the second emissive layer EL2 may emit green light of the second color, and the third emissive layer EL3 may emit blue light of the third color.

The deposition process of the emissive layers EL1, EL2 and EL3 may be performed such that the material for the emissive layers is deposited in an inclined direction rather than the direction perpendicular to the upper surface of the substrate 110. Accordingly, the emissive layers EL1, EL2 and EL3 may be deposited on the space between the pixel electrodes AE1, AE2 and AE3 and the inorganic pixel-defining layer 151 and on the side surfaces of the bank structure 160.

In some embodiments, the common electrodes CE1, CE2 and CE3 may be disposed on the emissive layers EL1, EL2 and EL3, respectively. The common electrodes CE1, CE2 and CE3 include a transparent conductive material so that lights generated in the emissive layers EL1, EL2 and EL3 may be output. The common electrodes CE1, CE2 and CE3 may receive a common voltage or a low-level voltage. When the pixel electrodes AE1, AE2 and AE3 receive the voltage equal to the data voltage and the common electrodes CE1, CE2 and CE3 receive the low-level voltage, a potential difference may be formed between the pixel electrodes AE1, AE2 and AE3 and the common electrodes CE1, CE2 and CE3, so that the emissive layers EL1, EL2 and EL3 may emit lights.

In an embodiment of the disclosure, the common electrodes CE1, CE2 and CE3 may include a material layer having a relatively small work function such as Li, Ca, LiF/Ca, LiF/Al, Al, Mg, Ag, Pt, Pd, Ni, Au, Nd, Ir, Cr, BaF and Ba, or a compound or combination thereof (e.g., a combination of Ag and Mg). The common electrodes CE1, CE2 and CE3 may further include a transparent metal oxide layer disposed on the material layer having a relatively small work function.

The common electrodes CE1, CE2 and CE3 may include a first common electrode CE1, a second common electrode CE2 and a third common electrode CE3 disposed in different emission areas EA1, EA2 and EA3. The first common electrode CE1 may be disposed on the first emissive layer EL1 in the first emission area EA1, the second common electrode CE2 may be disposed on the second emissive layer EL2 in the second emission area EA2, and the third common electrode CE3 may be disposed on the third emissive layer EL3 in the third emission area EA3. The common electrodes CE1, CE2 and CE3 disposed in different emission areas EA1, EA2 and EA3 may be electrically connected through the bank structure 160.

A capping layer 159 may be disposed on the common electrodes CE1, CE2 and CE3. The capping layer 159 may include an inorganic insulating material to cover the light-emitting elements ED1, ED2 and ED3 and patterns disposed on the bank structure 160. The capping layer 159 may prevent the light-emitting elements ED1, ED2 and ED3 from being damaged by outside air and may prevent the patterns disposed on the bank structure 160 from being delaminated during the process of fabricating the display device 10.

In an embodiment of the disclosure, the capping layer 159 may include aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O).

Referring to FIG. 6, the display device 10 may include organic patterns ELP1, ELP2 and ELP3, electrode patterns CEP1, CEP2 and CEP3, and capping patterns 159a disposed on the bank structure 160. The organic patterns ELP1, ELP2 and ELP3, the electrode patterns CEP1, CEP2 and CEP3, and the capping patterns 159a may be disposed on the bank structure 160, and may surround the emission areas EA1, EA2 and EA3 or the first openings OP1. The shapes of the organic patterns ELP1, ELP2 and ELP3, the electrode patterns CEP1, CEP2 and CEP3, and the capping patterns 159a disposed around the emission areas EA1, EA2 and EA3 may be formed by being partially etched during the fabrication process.

The organic patterns ELP1, ELP2 and ELP3 may be disposed on a fourth bank layer 167. The organic patterns ELP1, ELP2 and ELP3 may include a first organic pattern ELP1, a second organic pattern ELP2 and a third organic pattern ELP3 including the same material as that of the emissive layers EL1, EL2 and EL3. The first organic pattern ELP1 may include the same material as that of the first emissive layer EL1, the second organic pattern ELP2 may include the same material as that of the second emissive layer EL2, and the third organic pattern ELP2 may include the same material as that of the third emissive layer ELP3.

The organic patterns ELP1, ELP2 and ELP3 may be formed as traces that are disconnected from the emissive layers EL1, EL2 and EL3 as the bank structure 160 includes portions protruding toward the openings OP1 and OP2. Accordingly, the organic patterns ELP1, ELP2 and ELP3 and the emissive layers EL1, EL2 and EL3 may be spaced apart from each other.

The electrode patterns CEP1, CEP2 and CEP3 may be disposed on the organic patterns ELP1, ELP2 and ELP3, respectively. The electrode patterns CEP1, CEP2 and CEP3 may include a first electrode pattern CEP1, a second electrode pattern CEP2 and the third electrode pattern CEP3 that include the same material as that of the common electrodes CE1, CE2, and CE3 of the light-emitting elements ED1, ED2 and ED3, respectively.

The arrangement relationship between the electrode patterns CEP1, CEP2 and CEP3 and the organic patterns ELP1, ELP2 and ELP3 may be identical to the arrangement relationship between the emissive layers EL1, EL2 and EL3 of the light-emitting elements ED1, ED2 and ED3 and the common electrodes CE1, CE2, and CE3. The electrode patterns CEP1, CEP2 and CEP3 may be traces that are formed as the deposited material is disconnected from the common electrodes CE1, CE2 and CE3 as the bank structure 160 includes portions protruding toward the openings OP1 and OP2. The electrode patterns CEP1, CEP2 and CEP3 may be spaced apart from the common electrodes CE1, CE2 and CE3. In some embodiments, the electrode patterns CEP1, CEP2 and CEP3 may not contact a first bank layer 161 or a second bank layer 163.

In some embodiments, the capping pattern 159a may be disposed on the electrode patterns CEP1, CEP2 and CEP3. The capping pattern 159a may include the same material as that of the capping layer 159 disposed on the common electrodes CE1, CE2 and CE3. The capping patterns 159a may be disposed directly on the first electrode pattern CEP1, the second electrode pattern CEP2, and the third electrode pattern CEP3, respectively. The arrangement relationship between the capping patterns 159a and the electrode patterns CEP1, CEP2 and CEP3 may be identical to the arrangement relationship between the common electrodes CE1, CE2 and CE3 and the capping layer 159. The capping patterns 159a may be traces that are formed as the deposited material is disconnected from the capping layer 159 as the bank structure 160 includes portions protruding toward the openings OP1 and OP2.

The thin-film encapsulation layer 170 may be disposed on the light-emitting elements ED1, ED2 and ED3 and the bank structure 160 and may cover the plurality of light-emitting elements ED1, ED2 and ED3 and the bank structure 160. The thin-film encapsulation layer 170 may include at least one inorganic film to prevent permeation of oxygen or moisture into the emission material layer 150. The thin-film encapsulation layer 170 may include at least one organic film to protect the emission material layer 150 from foreign substances such as dust.

In an embodiment of the disclosure, the thin-film encapsulation layer 170 may include a first encapsulation layer 171, a second encapsulation layer 173, and a third encapsulation layer 175 sequentially stacked on one another. The first encapsulation layer 171 and the third encapsulation layer 175 may be inorganic encapsulation layers, and the second encapsulation layer 173 disposed therebetween may be an organic encapsulation layer.

Each of the first encapsulation layer 171 and the third encapsulation layer 175 may include one or more inorganic insulating materials. The inorganic insulating materials may include aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O).

The second encapsulation layer 173 may include a polymer-based material. The polymer-based material may include an acrylic resin, an epoxy resin, polyimide, polyethylene, etc. In an embodiment, the second encapsulation layer 173 may include an acrylic resin, e.g., polymethyl methacrylate, polyacrylic acid, etc., for example. The second encapsulation layer 173 may be formed by curing a monomer or by applying a polymer.

The first encapsulation layer 171 may be disposed on the light-emitting elements ED1, ED2 and ED3, a plurality of patterns, and the bank structure 160. The first encapsulation layer 171 may include first to third inorganic layers 171-1, 171-2 and 171-3 disposed in different emission areas EA1, EA2 and EA3, respectively. The first to third inorganic layers 171-1, 171-2 and 171-3 may include an inorganic insulating material to cover the light-emitting elements ED1, ED2 and ED3, respectively. The first to third inorganic layers 171-1, 171-2 and 171-3 may prevent the light-emitting elements ED1, ED2 and ED3 from being damaged by outside air and may prevent the patterns disposed on the bank structure 160 from being delaminated during the process of fabricating the display device 10.

In some embodiments of the disclosure, the first to third inorganic layers 171-1, 171-2 and 171-3 may be disposed directly on the capping layer 159 in the first openings OP1 and may be disposed directly on the capping patterns 159a in the second openings OP2.

Although the first to third inorganic layers 171-1, 171-2 and 171-3 may be disposed in the same layer, they may be formed via different processes during the process of fabricating the display device 10. In an embodiment, the emissive layers EL1, EL2 and EL3 of the first to third light-emitting elements ED1, ED2 and ED3 may not be formed simultaneously but may be formed via different processes, for example. Similarly, the first to third inorganic layers 171-1, 171-2 and 171-3 may be formed via different processes.

In an embodiment of the disclosure, the first inorganic layer 171-1 may be formed after the first common electrode CE1 is formed, the second inorganic layer 171-2 may be formed after the second common electrode CE2 is formed, and the third inorganic layer 171-3 may be formed after the third common electrode CE3 is formed. That is to say, the first inorganic layer 171-1 may be formed prior to the second light-emitting element ED2 and the third light-emitting element ED3, and the second inorganic layer 171-2 may be formed prior to the third light-emitting element ED3.

The touch sensing layer 180 may be disposed on the thin-film encapsulation layer 170. The touch sensing layer 180 may include a touch buffer layer 181, a touch insulating layer 183, touch electrodes TE, and a touch protective layer 185.

The touch buffer layer 181 may be disposed on the thin-film encapsulation layer 170. The touch buffer layer 181 may be insulating and optical functions. The touch buffer layer 181 may include at least one inorganic film. Optionally, the touch buffer layer 181 may be eliminated. Although not shown in the drawings, the connection electrodes electrically connecting between the touch electrodes may be disposed on the touch buffer layer 181.

The connection electrodes may be made up of a single layer of molybdenum (Mo), titanium (Ti), copper (Cu), aluminum (Al), or indium tin oxide (“ITO”), or may be made up of a stack structure of aluminum and titanium (Ti/Al/Ti), a stack structure of aluminum and ITO (ITO/Al/ITO), an APC alloy and a stack structure of an APC alloy and ITO (ITO/APC/ITO).

The touch insulating layer 183 may cover the touch buffer layer 181. The touch insulating layer 183 may have insulating and optical functions. In an embodiment, the touch insulating layer 183 may be an inorganic layer including at least one selected from the group consisting of a silicon nitride layer, a silicon oxynitride layer, a silicon oxide layer, a titanium oxide layer and an aluminum oxide layer, for example.

Some of the touch electrodes TE may be disposed on the touch insulating layer 183. The touch electrodes TE may not overlap with the first to third emission areas EA1, EA2 and EA3. The touch electrodes TE may be made up of a single layer of molybdenum (Mo), titanium (Ti), copper (Cu), aluminum (Al), or indium tin oxide (“ITO”), or may be made up of a stack structure of aluminum and titanium (Ti/Al/Ti), a stack structure of aluminum and ITO (ITO/Al/ITO), an APC alloy and a stack structure of an APC alloy and ITO (ITO/APC/ITO).

The touch protective layer 185 may cover the touch electrodes TE and the touch insulating layer 183. The touch protective layer 185 may have insulating and optical functions. The touch protective layer 185 may include or consist of any of the above-listed materials as embodiments of the touch insulating layer 183.

A light-blocking layer BM may be disposed on the touch sensing layer 180. The light-blocking layer BM may overlap the inorganic pixel-defining layer 151 and the bank structure 160.

The light-blocking layer BM may include a light-absorbing material. In an embodiment, the light-blocking layer BM may include an inorganic black pigment or an organic black pigment, for example. The inorganic black pigment may be, but is not limited to, carbon black, and the organic black pigment may include, but is not limited to, at least one of lactam black, perylene black, and aniline black. The light-blocking layer BM may prevent visible light from penetrating and mixing colors between the first to third emission areas EA1, EA2 and EA3 to improve the color gamut of the display device 10.

The color filter layer 190 may overlap with the emission areas EA1, EA2 and EA3 and may be disposed on the touch protective layer 185 and the light-blocking layer BM.

The color filter layer 190 may include a first color filter 191, a second color filter 193 and a third color filter 195 disposed in different emission areas EA1, EA2 and EA3, respectively. The color filters 191, 193 and 195 may include a colorant such as a dye and pigment that absorbs lights in wavelength ranges other than light in a particular wavelength range, and may be disposed in association with the lights exiting from the emission areas EA1, EA2 and EA3. In an embodiment, the first color filter 191 may be a red color filter that is disposed to overlap with the first emission area EA1 and transmits only first red light, for example. The second color filter 193 may be a green color filter that is disposed to overlap with the second emission area EA2 and transmits only green second light. The third color filter 195 may be a blue color filter that is disposed to overlap with the third emission area EA3 and transmits only blue third light.

Although the color filters 191, 193 and 195 are spaced apart from one another on the light-blocking layer BM in the example shown in FIG. 6, the disclosure is not limited thereto. In other words, the color filters 191, 193 and 195 may partially overlap with one another. Different color filters 191, 193 and 195 may not overlap with the emission areas EA1, EA2 and EA3 and may overlap with one another on the light-blocking layer BM.

The overcoat layer OC may be disposed over the color filter layer 190 and the light-blocking layer BM to provide a flat surface over the color filters 191, 193 and 195. The overcoat layer OC may be a colorless light-transmitting layer having no color in the visible light band. In an embodiment, the overcoat layer OC may include a colorless light-transmitting organic material such as an acryl-based resin, for example.

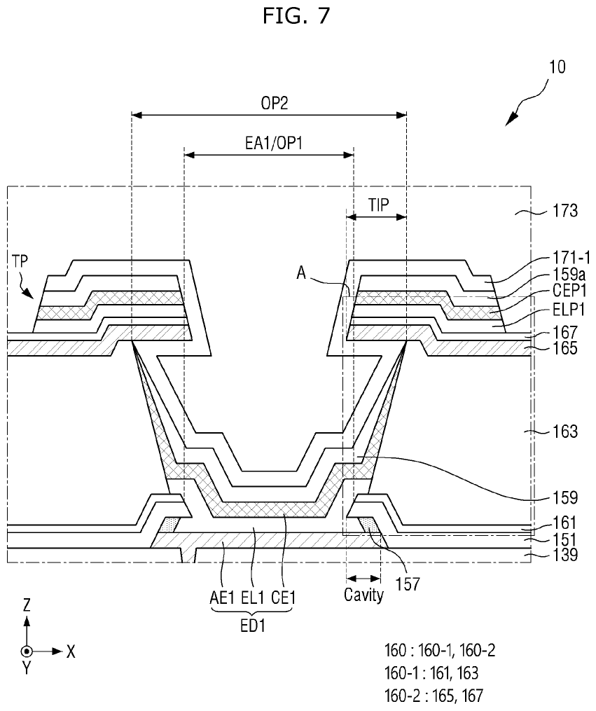

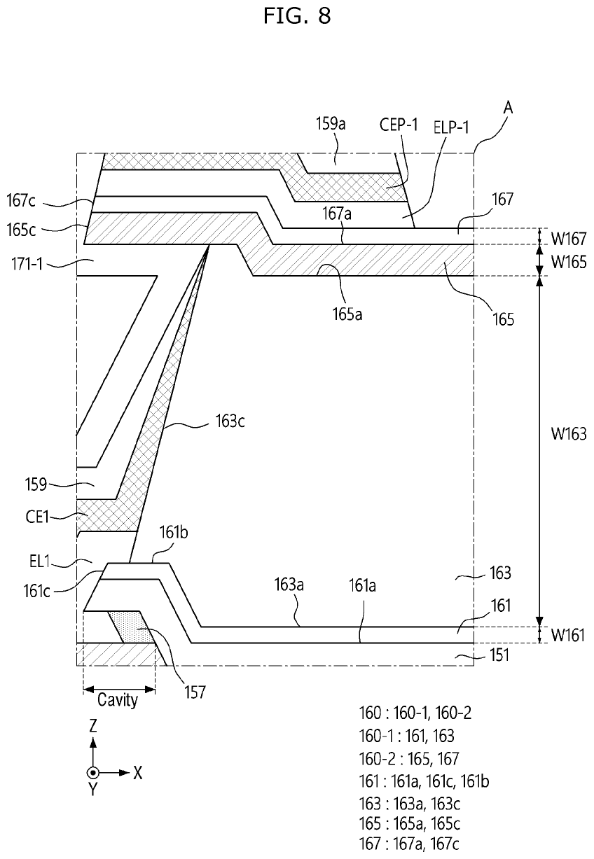

FIG. 7 is a cross-sectional view showing the first emission area EA1 of FIG. 6. FIG. 8 is an enlarged view of area A of FIG. 7. FIG. 7 is a view showing a first light-emitting element ED1 disposed in a first emission area EA1 and a nearby part of the bank structure 160.

Referring to FIG. 7, the inorganic pixel-defining layer 151 may be disposed on the first pixel electrode AE1 and may be spaced apart from the first pixel electrode AE1 in a third direction (z-axis direction). Accordingly, a cavity may be formed between the inorganic pixel-defining layer 151 and the first pixel electrode AEL1. The cavity may be an area in line with a protruding tip of the bank structure 160 to be described later.

In some embodiments, a part of the temporary protective layer may remain as a residual pattern 157 in the cavity. In other words, a part of the first emissive layer EL1 and the residual pattern 157 may be disposed inside the cavity of the display device 10. The first emissive layer EL1 may be disposed inside the cavity because the emissive layers EL1, EL2, and EL3 are deposited obliquely. In addition, the residual pattern 157 may be disposed inside the cavity because the temporary protective layer was disposed.

In some embodiments, the bank structure 160 may include a first base 160-1 and a second base 160-2. The first base 160-1 may include the first bank layer 161 and the second bank layer 163, and the second base 160-2 may include the third bank layer 165 and the fourth bank layer 167. The first bank layer 161 may be the lowest layer of the bank structure 160, the fourth bank layer 167 may be the uppermost layer of the bank structure 160, and the second bank layer 163 and the third bank layer 165 may be intermediate layers of the bank structure 160.

In some embodiments, the first base 160-1 may provide electrical stability to the display device 10.

Referring to FIG. 7, the first bank layer 161 may be disposed on the inorganic pixel-defining layer 151. The first bank layer 161 may include a metal material that has excellent metal adhesion and is relatively stable in a wet etching process. In addition, the first bank layer 161 may have good electrical conductivity. In an embodiment, the first bank layer 161 may include, but is not limited to, titanium (Ti), for example.

The first bank layer 161 may be electrically connected to the first common electrode CE1. The common electrodes CE1, CE2 and CE3 overlapping with different emission areas EA1, EA2 and EA3 are not directly connected, but may be electrically connected through the first bank layer 161 of the bank structure 160.

Referring to FIG. 8, the first bank layer 161 may include a first surface 161a in contact with the inorganic pixel-defining layer 151, a second surface 161b facing the first surface 161a, and a side surface 161c. The first surface 161a of the first bank layer 161 may be in direct contact with the inorganic pixel-defining layer 151 and may cover an entirety of one surface of the inorganic pixel-defining layer 151 facing the bank structure 160. In addition, the side surface 161c of the first bank layer 161 may protrude toward a first opening OP1 than the side surface 163c of the second bank layer 163. Accordingly, a part of the second surface 161b of the first bank layer 161 and the side surface 161c of the first bank layer 161 may be in direct contact with the first emissive layer EL1. In an embodiment, the thickness W161 of the first bank layer 161 of the display device 10 may be greater than or equal to 100 angstroms (Å) and less than or equal to 150 Å, for example, but the disclosure is not limited thereto.

Referring to FIG. 7, the second bank layer 163 may be disposed on the first bank layer 161. The second bank layer 163 may include a metal layer having relatively high electrical conductivity and reflectivity, and for example, the second bank layer 163 may include copper (Cu).

In some embodiments, the second bank layer 163 may electrically connect the common electrodes CE1, CE2 and CE3 overlapping with different emission areas EA1, EA2 and EA3, respectively. In other words, the light-emitting elements ED1, ED2 and ED3 disposed in different emission areas EA1, EA2 and EA3, respectively, may be electrically connected through the first bank layer 161 and the second bank layer 163 of the bank structure 160.

Referring to FIG. 8, the second bank layer 163 may include a first surface 163a in contact with the first bank layer 161, and a side surface 163c facing the first opening OP1 and the second opening OP2.

The first surface 163a of the second bank layer 163 may not cover an entirety of the second surface 161b of the first bank layer 161. Accordingly, a part of the second surface 161b of the first bank layer 161 facing the openings OP1 and OP2 may be exposed. The exposed part of the second surface 161b of the first bank layer 161 may be covered by the first emissive layer EL1.

In some embodiments, the area of the first common electrode CE1 in contact with the side surface 163c of the second bank layer 163 may be greater than the area of the first emissive layer EL1 in contact with the side surface 163c of the second bank layer 163. Although the entirety of the first common electrode CE1 contacts the side surface 163c of the second bank layer 163 in the drawings, but the disclosure is not limited thereto. The first common electrode CE1 may be partially disposed in contact with the second bank layer 163 as long as it covers the first emissive layer EL1.

In some embodiments, the first bank layer 161 and the second bank layer 163 may be formed by a wet etch process. In some embodiments, the second bank layer 163 may have a higher etch rate than the first bank layer 161. As a result, the side surface 161c of the first bank layer 161 may protrude further toward the first opening OP1 and the second opening OP2 than the side surface 163c of the second bank layer 163. The side surface 163c of the second bank layer 163 may have an inclined surface shape inclined to the first direction X from the third direction (z-axis direction).

In some embodiments, the thickness W163 of the second bank layer 163 may be greater than the thickness W161 of the first bank layer 161. In an embodiment, the thickness W163 of the second bank layer 163 may range from 5,000 Å to 8,000 Å, for example.

In some embodiments, the second base 160-2 may reduce reflection of external light of the display device 10.

Referring to FIG. 7, the third bank layer 165 may be disposed on the second bank layer 163. The third bank layer 165 may include a transparent metal layer and may be a material that is stable during an etching process. In an embodiment, the third bank layer 165 may be indium zinc oxide (In₂O₃-ZnO; IZO), and the first bank layer 161/the second bank layer 163/the third bank layer 165 may have, but is not limited to, the structure of a titanium (Ti)/copper (Cu)/indium zinc oxide (“IZO”), for example.

In some embodiments, the third bank layer 165 may be formed by a wet etching process. The third bank layer 165 may include a material that is more stable during an etching process than the second bank layer 163. Accordingly, the third bank layer 165 may protrude toward the first opening OP1 than the second bank layer 163.

Referring to FIG. 8, the third bank layer 165 may include a first surface 165a in contact with the second bank layer 163, and a side surface 165c facing the first opening OP1 and the second opening OP2. In some embodiments, the side surface 163c of the second bank layer 163 may have a shape recessed inward from the side surface 165c of the third bank layer 165. Accordingly, the third bank layer 165 of the bank structure 160 may include a tip TIP protruding toward the first opening OP1. An undercut may be formed between the bottom of the tip TIP of the third bank layer 165 and the side surface 163c of the second bank layer 163.

In some embodiments, the thickness W165 of the third bank layer 165 may be smaller than the thickness W163 of the second bank layer 163 and larger than the thickness W161 of the first bank layer 161. In an embodiment, the thickness W165 of the third bank layer 165 may range from 400 Å to 500 Å, for example.

Referring to FIG. 7, the fourth bank layer 167 may be disposed on the third bank layer 165. The fourth bank layer 167 may include a transluscent metal material having a relatively high absorption coefficient and relatively low reflectance in the visible ray range. The fourth bank layer 167 is the uppermost layer of the bank structure 160 and may reduce reflection by external light. In an embodiment, the fourth bank layer 167 may include, but is not limited to, titanium (Ti), for example.

In some embodiments, the fourth bank layer 167 may be formed by a wet etching process. The fourth bank layer 167 may include a material that is more stable during an etching process than the second bank layer 163. Accordingly, the fourth bank layer 167 may protrude toward the first opening OP1 like the third bank layer 165. In other words, the fourth bank layer 167 may include a tip TIP protruding toward the first opening OP1.

Referring to FIG. 8, the fourth bank layer 167 may include a first surface 167a in contact with the third bank layer 165, and a side surface 167c facing the first opening OP1.

In some embodiments, the first surface 167a of the fourth bank layer 167 may cover along the third bank layer 165, and the side surface 167c of the fourth bank layer 167 may be extended in alignment with the side surface 165c of the third bank layer 165.

In some embodiments, the thickness W167 of the fourth bank layer 167 may be smaller than the thickness W163 of the second bank layer 163 and the thickness W165 of the third bank layer 165. In an embodiment, the thickness W167 of the fourth bank layer 167 may range from 100 Å to 150 Å, for example.

In some embodiments, the transmittance and extinction coefficient of the fourth bank layer 167 may be adjusted by adjusting the thickness W167 of the fourth bank layer 167. In an embodiment, when the fourth bank layer 167 has a thickness W167 from 100 Å to 150 Å, the fourth bank layer 167 may include translucent properties, for example. The fourth bank layer 167 may include the extinction coefficient of 1.72 in the visible range.

Referring back to FIG. 6, the materials for the emissive layers EL1, EL2 and EL3 and the common electrodes CE1, CE2 and CE3 may not be sufficiently deposited under the protruding tips TIP of the bank structure 160.

For this reason, the materials for the emissive layers EL1, EL2 and EL3 and the common electrodes CE1, CE2, and CE3 are deposited in an inclined direction rather than in the third direction Z perpendicular to the upper surface of the substrate. By doing so, the materials may be deposited even under the protruding tips of the bank structure 160. In an embodiment, the deposition process of forming the emissive layers EL1, EL2 and EL3 may be performed so that the materials are deposited in a direction that is not perpendicular to the upper surface of the pixel electrodes AE1, AE2 and AE3, e.g., in an inclined direction between the first direction X and the third direction Z, for example.

In an embodiment of the disclosure, the angle of the deposition process of forming the emissive layers EL1, EL2 and EL3 is defined as a first angle. The deposition process of forming the emissive layers EL1, EL2 and EL3 may be performed at an angle of 45° to 50° from the upper surface of the pixel electrodes AE1 and AE2 and AE3. That is to say, the first angle may range from 45° to 50°. Accordingly, the emissive layers EL1, EL2 and EL3 may be formed to fill the cavities between the pixel electrodes AE1, AE2 and AE3 and the inorganic pixel-defining layer 151, and may be formed also on the sidewalls of the second opening OP2 hidden by the protruding tip TIP of the bank structure 160.

The deposition process of forming the common electrodes CE1, CE2 and CE3 may be performed so that the materials are deposited in a direction that is not perpendicular to the upper surface of the pixel electrodes AE1, AE2 and AE3, e.g., in an inclined direction between the first direction X and the third direction Z.

In an embodiment of the disclosure, the angle of the deposition process of forming the common electrodes CE1, CE2 and CE3 is defined as a second angle. The deposition process of forming the common electrodes CE1, CE2 and CE3 may be performed obliquely with respect to the upper surface of the pixel electrodes AE1 and AE2 and AE3 by an angle of 30° to 50°.

In other words, the deposition process of forming the common electrodes CE1, CE2 and CE3 may be performed in a relatively horizontal direction compared to the deposition process of forming the emissive layers EL1, EL2 and EL3. Accordingly, the contact area between the common electrodes CE1, CE2 and CE3 and the side surface of the second bank layer 163 may be larger than the contact area between the emissive layers EL1, EL2 and EL3 and the side surface of the second bank layer 163. Accordingly, the deposition process of forming the common electrodes CE1, CE2 and CE3 may have higher step coverage characteristics than the deposition process of forming the emissive layers EL1, EL2 and EL3.

That is to say, the common electrodes CE1, CE2 and CE3 may be deposited to a higher position on the side surface 163c of the second bank layer 163 than the emissive layers EL1, EL2 and EL3.

Referring to FIG. 7, the first inorganic layer 171-1 may be disposed on the first light-emitting element ED1. The first inorganic layer 171-1 may be disposed along the first light-emitting element ED1 and the inner sidewalls of the second opening OP2 to cover them. In addition, the first inorganic layer 171-1 may be disposed on the bank structure 160 and may cover a first organic pattern ELP1 a first electrode pattern CEP1 and a capping pattern 159a disposed around the first opening OP1. The first to third inorganic layers 171-1, 171-2 and 171-3 may be partially disposed on the bank structure 160 around the emission areas EA1, EA2 and EA3.

In some embodiments, the first organic pattern ELP1, the first electrode pattern CEP1, the capping pattern 159a and the first inorganic layer 171-1 on the fourth bank layer 167 may be partially patterned via an etching process. As a result, a trench TP may be formed in the first organic pattern ELP1, the first electrode pattern CEP1, the capping pattern 159a and the first inorganic layer 171-1 outside the second opening OP2.

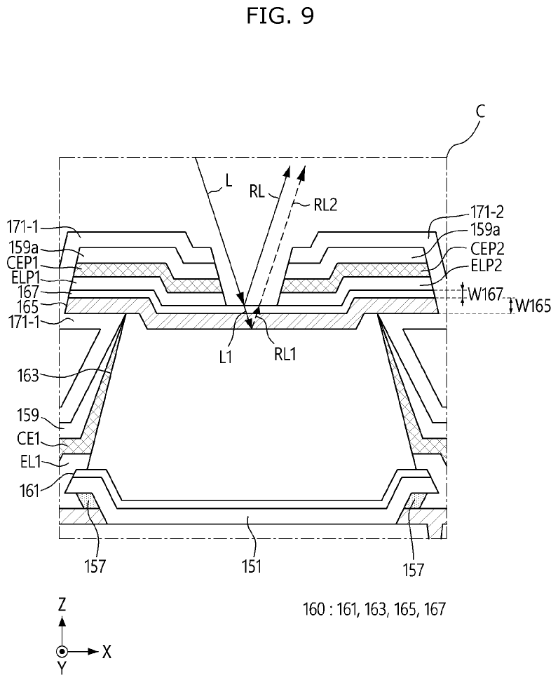

FIG. 9 is an enlarged, cross-sectional view of area C of FIG. 6. FIG. 9 is a cross-sectional view showing light incident on the bank structure 160 from the outside of the display device 10.

Referring to FIG. 9, light incident on the bank structure 160 from the outside of the display device 10 may be expressed as external light L. After the external light L is incident into the bank structure 160, it may be changed into first light L1 and reflected light RL. Specifically, the first light L1 may include light incident on the fourth bank layer 167 including a transluscent metal layer and the third bank layer 165 including a transparent metal layer, and the reflected light RL may include light reflected from the surface of the bank structure 160.

In some embodiments, the first light L1 may be converted into first reflected light RL1 reflected from the surface of the second bank layer 163. The first reflected light RL1 may include light reflected by the second bank layer 163 having relatively low transmittance and relatively high reflectance. The first reflected light RL1 may be partially cancelled in the third bank layer 165 and the fourth bank layer 167, and another part thereof may be reflected from the surface of the fourth bank layer 167 as the second reflected light RL2.

In some embodiments, when many reflected lights RL and RL2 are formed in the display device 10, poor visibility of the display device 10 may be caused. Specifically, the reflected lights RL and RL2 including wavelengths in the visible range (from 450 nanometers (nm) to 650 nm) may deteriorate the user's visibility.

Typically, the display device 10 may induce cancellation of a plurality of reflected lights RL and RL2 by adjusting physical properties and thicknesses of the third bank layer 165 and the fourth bank layer 167. This may reduce reflectance of the display device 10. Specifically, by the refractive indices of the third bank layer 165 and the fourth bank layer 167 in the visible range and the thicknesses W165 and W167 of the third bank layer 165 and the fourth bank layer 167, destructive interference may be calculated. In other words, by the refractive indices of the third bank layer 165 and the fourth bank layer 167 in the visible range and the thicknesses W165 and W167 of the third bank layer 165 and the fourth bank layer 167, the incident light and the reflected light of the display device 10 may be cancelled. In an embodiment, the first light Li and the first reflected light RL1 may be cancelled when the refractive indices n1 and n2 and the thicknesses W165 and W167 of the third and fourth bank layers 165 and 167 satisfy Equation 1 below, for example:

(W165+W167)≈{(λ/4)×(1/n1)}+{(λ/4)×(1/n2)} [Equation 1]

where λ denotes the wavelength of the external light L, n1 denotes the refractive index of the third bank layer 165, and n2 denotes the refractive index of the fourth bank layer 167. In an embodiment, the third bank layer 165 may have the refractive index of 1.99 with respect to the wavelength of 550 nm, and the fourth bank layer 167 may have the refractive index of 2.03 with respect to the wavelength of 550 nm, for example. Accordingly, the thickness W165 of the third bank layer 165 that allows the first light L1 (incident light) and the first reflected light RL1 (reflected light) to be cancelled may range from 400 Å to 500 Å, and the thickness W167 of the fourth bank layer 167 may range from 100 Å to 150 Å. Herein, in the visible range (380 nm to 780 nm), the reflectance of the display device 10 may be 7.8% at 450 nm, 6.0% at 550 nm, and 9.7% at 650 nm.

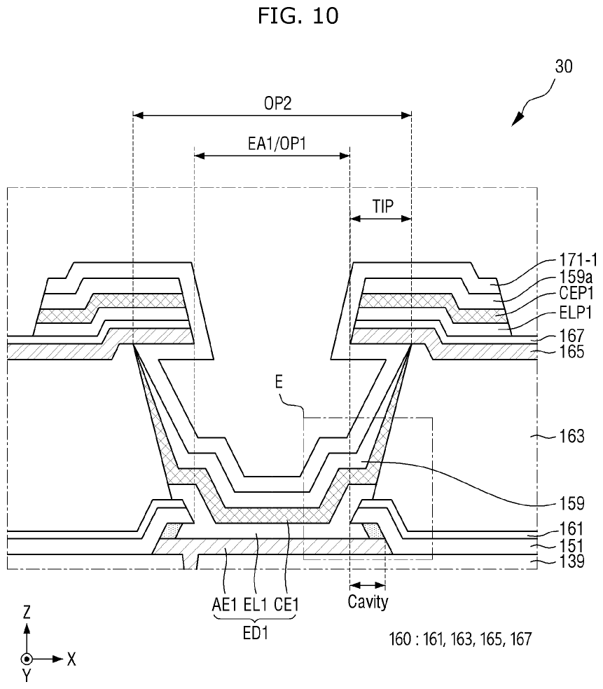

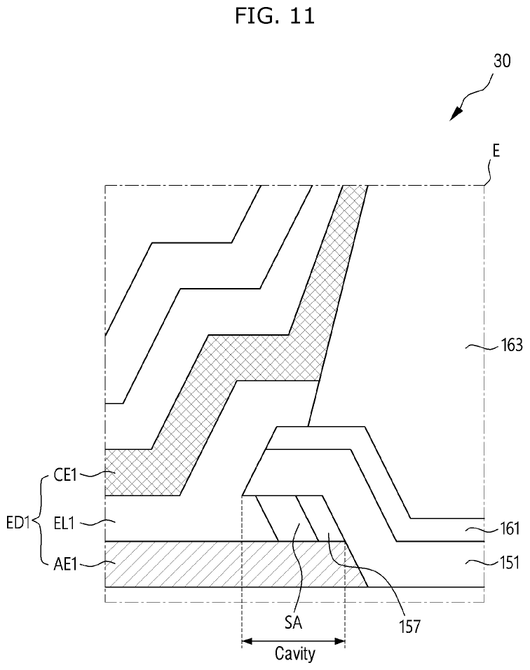

FIG. 10 is a cross-sectional view showing another embodiment of the first emission area of FIG. 6. FIG. 11 is an enlarged cross-sectional view of area E of FIG. 10.

Referring to FIG. 10, an inorganic pixel-defining layer 151 of a display device 30 may be disposed on a first pixel electrode AE1 and may be spaced apart from the first pixel electrode AE1 in the third direction (z-axis direction). That is to say, a cavity may be formed between the inorganic pixel-defining layer 151 and the first pixel electrode AEL1. The cavity may be in line with a protruding tip of a second opening OP2 and a bank structure 160.

Referring to FIG. 11, space SA may be defined between a first emissive layer EL1 and a residual pattern 157 in the cavity included in the display device 30. The space SA may be created depending on the degree of etching of a temporary protective layer and the degree of deposition of the emissive layers EL1, EL2 and EL3 during the process of fabricating the display device 30.

In some embodiments, the space SA may be surrounded by the first pixel electrode AE1, the first emissive layer EL1, the inorganic pixel-defining layer 151 and the residual pattern 157.

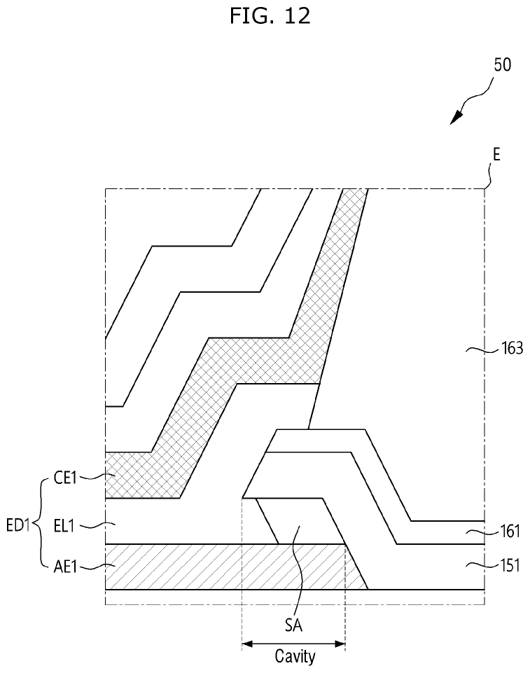

FIG. 12 is an enlarged, cross-sectional view of area E of another embodiment of FIG. 10.

A display device 50 of FIG. 12 is different from the display device 10 and the display device 30 in that a residual pattern 157 is not disposed inside a cavity between an inorganic pixel-defining layer 151 and a first pixel electrode AE1. In other words, in the display device 50, a temporary protective layer may be completely removed during the fabrication process, and thus no residual pattern 157 may remain. At the position where the temporary protective layer was, the inorganic pixel-defining layer 151 and the first pixel electrode AE1 are spaced apart from each other.

In some embodiments, portions of the emissive layers EL1, EL2 and EL3 may be disposed inside the cavity of the display device 50. However, it may be difficult to deposit the emissive layers EL1, EL2 and EL3 up to the inside of the cavity of the display device 50 due to the limitation of the deposition angle. Accordingly, only the space SA may be defined inside the cavity of the display device 50.

In some embodiments, the space SA may be surrounded by a first pixel electrode AE1, a first emissive layer EL1 and an inorganic pixel-defining layer 151.

Embodiments of the disclosure should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate;
a first electrode disposed on the substrate;
a pixel-defining layer disposed on the substrate and defining a first opening overlapping with the first electrode;
a bank structure disposed on the pixel-defining layer and defining a second opening overlapping with the first opening, the bank structure comprising:
a first base disposed on the pixel-defining layer and comprising a conductive material, and
a second base disposed on the first base and comprising a tip protruding toward the first opening than a side surface of the first base, the second base comprising:
a first bank layer disposed on the first base and comprising a transparent conductive material; and
a second bank layer disposed on the first bank layer and comprising a conductive material different from that of the first bank layer;
a first emissive layer disposed on the first electrode and disposed in the first opening; and
a second electrode disposed on the first emissive layer and in contact with the bank structure in the second opening.

2. The display device of claim 1, wherein a thickness of the first bank layer in a direction perpendicular to the substrate is greater than a thickness of the second bank layer.

3. The display device of claim 2, wherein a refractive index of the first bank layer is smaller than a refractive index of the second bank layer.

4. The display device of claim 3, wherein an amount of lights reflected by the bank structure is reduced by destructive interference between first light incident through the second base and reflected light reflected from a surface of the first base toward the outside.

5. The display device of claim 4, wherein the first bank layer comprises indium-zinc oxide, and the second bank layer comprises titanium (Ti).

6. The display device of claim 4, wherein the thickness of the first bank layer ranges from 400 angstroms to 500 angstroms, and the thickness of the second bank layer ranges from 100 angstroms to 150 angstroms.

7. The display device of claim 1, wherein one surface of the first emissive layer and one surface of the second electrode contact the first base in the second opening, wherein a contact area of the first emissive layer in contact with the first base is smaller than a contact area of the second electrode in contact with the first base.

8. The display device of claim 7, wherein the first base further comprises:
a first base bank layer disposed on the pixel-defining layer and comprising a same material as a material of the second bank layer; and
a second base bank layer disposed on the first base bank layer and comprising a conductive material different from that of the first base bank layer.

9. The display device of claim 8, wherein the first base bank layer further comprises a first surface in contact with the pixel-defining layer, a second surface facing the first surface, and a side surface,
wherein the first surface of the first base bank layer covers an entirety of a surface of the pixel-defining layer,
wherein the side surface of the first base bank layer protrudes toward the first opening than a side surface of the second base bank layer, and
wherein the second surface and the side surface of the first base bank layer are partially in contact with the first emissive layer.

10. The display device of claim 9, wherein the first base bank layer comprises titanium (Ti), and the second base bank layer comprises copper (Cu).

11. The display device of claim 9, wherein a thickness of the second base bank layer in a direction perpendicular to the substrate is greater than a thickness of the first base bank layer in the direction perpendicular to the substrate,
wherein the thickness of the first base bank layer ranges from about 100 angstroms to about 150 angstroms, and
wherein the thickness of the second base bank layer ranges from about 5,000 angstroms to about 8,000 angstroms.

12. The display device of claim 1, further comprising:
a third electrode spaced apart from the first electrode with the pixel-defining layer therebetween;
a second emissive layer on the third electrode;
a fourth electrode on the second emissive layer; and
a thin-film encapsulation layer disposed on the second electrode, the bank structure, and the fourth electrode,
wherein the thin-film encapsulation layer comprises a first encapsulation layer; a second encapsulation layer on the first encapsulation layer; and a third encapsulation layer on the second encapsulation layer,
wherein the first encapsulation layer further comprises a first inorganic layer disposed on the second electrode and the second bank layer; and a second inorganic layer disposed on the fourth electrode and the second bank layer, and
wherein the first inorganic layer and the second inorganic layer are spaced apart from each other.

13. The display device of claim 12, wherein the second bank layer and the second encapsulation layer contact each other where the first inorganic layer and the second inorganic layer included in the first encapsulation layer are spaced apart from each other.

14. The display device of claim 13, further comprising:
a first organic pattern disposed on the second bank layer of the second base to surround the first opening, and comprising a same material as a material of the first emissive layer; and
a first electrode pattern disposed on the first organic pattern and comprising a same material as a material of the second electrode,
wherein the first organic pattern and the first electrode pattern overlap with the tip of the second base,
wherein the first emissive layer and the first organic pattern are spaced apart from each other, and
wherein the second electrode and the first electrode pattern are spaced apart from each other.

15. The display device of claim 1, further comprising:
a pattern disposed between the first electrode and the pixel-defining layer,
wherein the pattern overlaps with the tip of the second base and the second opening, and
wherein the pattern is surrounded by the first emissive layer, the pixel-defining layer and the first electrode.

16. The display device of claim 15, wherein the pattern comprises aluminum-zinc oxide (“AZO”) doped with aluminum, and a content of aluminum (Al) in the pattern ranges from 2% to 5%.

17. A display device comprising:
a substrate;
a first electrode disposed on the substrate;
a pixel-defining layer disposed on the substrate and defining a first opening overlapping with the first electrode;
a bank structure disposed on the pixel-defining layer and defining a second opening overlapping with the first opening, the bank structure comprising:
a first base disposed on the pixel-defining layer and comprising a conductive material; and
a second base disposed on the first base and comprising a tip protruding toward the first opening than a side surface of the first base;
a first emissive layer disposed on the first electrode and disposed in the first opening; and
a second electrode disposed on the first emissive layer and in contact with the bank structure in the second opening,
wherein a cavity is defined between a surface of the first electrode and the pixel-defining layer,
wherein the first emissive layer is further disposed in the cavity, and
wherein the cavity overlaps with the second opening and the tip of the second base.

18. The display device of claim 17, wherein the cavity is surrounded by the first emissive layer, the pixel-defining layer and the first electrode,
wherein a pattern and a space are further defined in the cavity, and
wherein the space is defined between the pattern and the first emissive layer.

19. The display device of claim 18, wherein the pattern comprises aluminum-zinc oxide (“AZO”), and a content of aluminum (Al) in the pattern ranges from 2% to 5%.

20. The display device of claim 17, further comprising:
a space defined in the cavity, wherein the space is surrounded by the first emissive layer, the pixel-defining layer and the first electrode, and overlaps with the tip of the bank structure and the second opening.
